(19) United States
(12) Patent Application Publication
(10) Pub. No.: US 2026/0147484 A1
(43) Pub. Date: May 28, 2026

(54) SYSTEM FIRMWARE ALGORITHM TO REDUCE READ ERRORS IN CASES OF CROSS-TEMPERATURE USING BACKGROUND DUMMY READ OPERATIONS

(71) Applicant: Microchip Technology Incorporated, Chandler, AZ (US)

(72) Inventors: Salvatrice Scommegna, CORNATE D'ADDA (IT); Pitamber Shukla, San Jose, CA (US); Michele Cirella, Castelmassa (IT); Antonio Aldarese, VIMERCATE (IT)

(73) Assignee: Microchip Technology Incorporated, Chandler, AZ (US)

(21) Appl. No.: 19/040,720

(22) Filed: Jan. 29, 2025

Related U.S. Application Data
(60) Provisional application No. 63/723,776, filed on Nov. 22, 2024.

(51) Int. Cl. G06F 3/06

(52) U.S. Cl. CPC G06F 3/0619; G06F 3/0653; G06F 3/0659; G06F 3/0679

(57) ABSTRACT

A computer-implemented method for increasing reliability of a current operation performed by a NAND flash device, the method comprising performing, via a flash controller, the steps of determining a temperature of the NAND flash device, determining that the temperature satisfies a threshold, and responsive to the determination that the threshold is satisfied, performing additional operations on the NAND flash device.

### CROSS-REFERENCE TO RELATED APPLICATIONS

The current patent application claims the benefit under 35 U.S.C. § 119(e) of the priority date of U.S. Provisional Application Ser. No. 63/723,776; titled “SYSTEM FIRMWARE ALGORITHM TO REDUCE READ ERRORS IN CASES OF CROSS-TEMPERATURE USING BACKGROUND DUMMY READ OPERATIONS”; and filed Nov. 22, 2024. The Provisional Application is hereby incorporated by reference, in its entirety, into the current patent application.

### TECHNICAL FIELD

Various examples of the present disclosure relate to systems and methods for reducing read errors in NOT-AND (NAND) flash devices (e.g., solid state drives (SSDs)) using background dummy operations.

### BACKGROUND

NAND flash devices, such as SSDs, may be susceptible to “cross-temperature.” Effects of cross-temperature may occur when a read temperature of a NAND flash device is different than a temperature of the NAND flash device when data was programmed, or vice-versa. Over time, repeated instances of cross-temperature in a NAND flash device can decrease reliability of operations being performed by, and can even shorten the lifespan of, the device. The present disclosure seeks to increase the reliability and lifespan of NAND flash devices by reducing/eliminating instances of cross-temperature.

This background discussion is intended to provide information related to the present invention which is not necessarily prior art.

### SUMMARY OF THE INVENTION

According to various examples of the present disclosure, a computer implemented method for increasing reliability of a current operation performed by a NAND flash device may include performing the following via a flash controller: determining a temperature of the NAND flash device; determining that the temperature satisfies a threshold; and, responsive to the determination that the threshold is satisfied, performing additional operations on the NAND flash device. The additional operations may include one or both of read operation(s) and program (or write) operation(s), and, once performed, these additional operations may heat the NAND flash device.

According to various examples of the present disclosure, a controller of a NAND flash device is provided that includes non-transitory media having instructions embodied/stored thereon. The instructions, when executed by at least one processor, may cause the processor(s) to: determine a temperature of the NAND flash device; determine that the temperature satisfies a threshold; and, responsive to the determination that the threshold is satisfied, perform additional operations on the NAND flash device. The additional operations may include one or both of read operation(s) and program operation(s), and these additional operations, once performed, may heat the NAND flash device.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates an example system for reducing cross-temperature in a NAND flash device;

FIG. 2 illustrates an example computing system of the system of FIG. 1 connected to a communication network;

FIG. 3 illustrates an example data storage system of the system of FIG. 1;

FIG. 4 illustrates an example non-volatile memory (NVM) media of the system of FIG. 1;

FIG. 5 illustrates an example multi-plane block of an NVM of the system of FIG. 1;

FIG. 6 illustrates an example multi-plane wordline (WL) of the multi-plane block of FIG. 5; and FIG. 7 illustrates an example method flow for reducing cross-temperature in a NAND flash device.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In various examples of the present disclosure, a data storage system may include a memory device and a controller. The memory device may store data. The data storage system may be connected to a host system. In various examples, the data storage system may be connected to the host system by wired or wireless means. In various examples, the data storage system may be connected to more than one host system, such as in a multi-tenant environment, without limitation. The controller may be operable to manage storage and retrieval of data to and from the memory device. The host system may send data to the data storage system for storage in the memory device. The controller may process the data and issue commands to the memory device for storing the data in the memory device. The host system may send a read request to the data storage system. The read request may indicate data to be retrieved from the memory device and sent back to the host system. The controller may process the read request, retrieve the data from the memory device, process the retrieved data, and send the retrieved data to the host system.

In various examples, the memory device may be a solid state drive (SSD) including a plurality of non-volatile memory (NVM) media (e.g., NAND-based memory media) for data storage. In various examples, the NVM media may include chip enable (CE) ports which may also be referred to as “targets.” Examples may be used in single-level cell (SLC) systems, multi-level cell (MLC) systems, triple-level cell (TLC) systems, quad-level cell (QLC) systems, and penta-level cell (PLC) systems, without limitation. Applications may include consumer hard drives, high performance computing (HPC), data transfer for AI, and data center solutions (DCS), without limitation.

The NVM media may respectively include a local controller and a plurality of die. In various examples, the NVM media may respectively include two (2), four (4), eight (8), sixteen (16), twenty four (24), thirty two (32), or more die, without limitation. Each die may correspond to a logical unit (LUN). Each LUN may include a plurality of planes. Each LUN may include, for example, four (4), six (6), eight (8), or more planes, without limitation. Each plane may include a cache register, a page register, and a plurality of physical memory blocks.

When data is written to or retrieved from the NVM media, the data may be temporarily stored in one of the cache register and the page register. Each physical memory block may include a set of pages. The cache register and the page register may respectively have an equivalent data capacity of one page. Accordingly, data to be written to a first page may be temporarily stored in the cache register while data to be written to another page may be temporarily stored in the page register. Data to be read from a first page may be retrieved and temporarily stored in the cache register while data to be read from another page may be stored in the page register. Accordingly, the cache register and page register enable double buffering of data to reduce data programming and read times. Each page may include a plurality of cells. Each cell may include a transistor having a gate, a source, and a drain. Data bits may be written to the plurality of cells on a page-by-page basis. Data may be erased from the plurality of cells on a physical memory block basis.

The NVM media may additionally include a plurality of wordlines (WLs) and a plurality of bit lines (BLs). Generally, WLs connect the gates of each cell included in a row of cells. BLs may be connected to the drain of each cell. A row of cells having their gates connected by a WL may be referred to as a page. BLs can either connect the drain of a cell to the source of a cell in an adjacent row or to “ground” (e.g., true ground, 0V, Vcc, etc.). When a voltage is applied to a specific WL, cells included in that WL are accessible for writing/programming or reading. Data is stored in and/or transferred to/from cells during read/write operations via BLs. In other words, WLs effectively address rows of cells where data is being programmed to or read from, while BLs are highways on which data travel to reach the desired cell(s).

In various examples, the cells may include single-level cells (SLCs), multi-level cells (MLCs), triple-level cells (TLCs), quadruple-level cells (QLCs), and/or penta-level cells (PLCs), without limitation. Accordingly, the wordlines may be SLC wordlines, MLC wordlines, QLC wordlines and/or PLC wordlines, without limitation. In an example, a TLC multi-plane wordline may span four (4) planes. The four (4) planes may respectively include a lower page, a middle page, and an upper page of the wordline. The lower page, middle page, and upper page may correspond to a page including a string of TLCs. The TLC multi-plane wordline may be activated to write data to each of the upper, middle, and lower pages of each of the four (4) planes. Accordingly, an SLC wordline may be associated with one (1) page from each plane, an MLC wordline may include two pages (2) from each plane, a TLC wordline may include three (3) pages from each plane, a QLC wordline may include four (4) pages from each plane, and a PLC wordline may include five (5) pages from each plane.

In various examples, the physical blocks of each LUN may be organized into multi-plane blocks. A multi-plane block may include a set of blocks of a particular LUN. For example, a first block of a first plane of a first LUN, a first block of a second plane of the first LUN, a first block of a third plane of the first LUN, and a first block of a fourth plane of the first LUN may be organized into a multi-plane block. Accordingly, each LUN may include a number of multi-plane blocks equal to a number of physical blocks in one plane of a particular LUN, and each multi-plane block may include one (1) physical block from each plane of the particular LUN.

Each physical block of each multi-plane block may include a set of pages and a set of WLs corresponding to the set of pages. Accordingly, each plane of the multi-plane block may have a set of pages and corresponding set of WLs. The WLs may be organized into multi-plane WLs spanning the planes of a multi-plane block. Each multi-plane WL may include one (1) WL from each plane of the multi-plane block. For example, a multi-plane WL may include a first WL from a first plane of a multi-plane block, a first WL from a second plane of the multi-plane block, a first WL from a third plane of the multi-plane block, and a first WL from a fourth plane of the multi-plane block. The first WL of the first plane may correspond to a first page of the first plane, the first WL of the second plane may correspond to a first page of the second plane, and so on. For a TLC multi-plane WL, each page (e.g., the first page of the first plane, the first page of the second plane) may include a lower page, a middle page, and an upper page. Accordingly, each WL of a TLC multi-plane WL may include three (3) pages. A total number of pages in a TLC multi-plane WL is a number of pages in each plane multiplied by a number of planes. For example, a TLC multi-plane WL of a four (4) plane NVM may include a total of twelve (12) pages.

In various examples, reliability of a current operation being performed by a NAND flash device may be maintained by, for example, determining a temperature of the NAND flash device, determining whether the temperature satisfies a threshold, and, in response to determining that the threshold is satisfied, performing additional (dummy) operations on the NAND flash device.

Broadly, “reliability” of a NAND flash device refers to the ability of the device to consistently store/retrieve (e.g., program/read, respectively) data over time, without errors. Reliability can naturally degrade over time and through use, for example because repeated program/read cycles performed on/by the device lead to such degradation in the blocks and cells of the device. While there are techniques, such as error correction and wear leveling, that seek to maintain the integrity of data stored on NAND flash devices, these techniques are insufficient. The present disclosure seeks to reduce instances of cross-temperature experienced by the NAND flash device, thereby increasing the reliability of operations currently being performed by the device.

As mentioned above, cross-temperature occurs when the temperature at which data is being read from a NAND flash device, such as an SSD, is significantly different than the temperature of the NAND flash device when the data was programmed. For instance, cross-temperature would occur if data were programmed to an SSD at one hundred degrees Celsius (100° C.) but is currently being read at ten degrees Celsius (10° C.). To mitigate cross-temperature, a controller included in/communicatively coupled to a NAND flash device may determine the temperature of the NAND flash device, e.g., generally or at a particular location within the NAND flash device.

The controller may determine that the current or present temperature satisfies a threshold. The threshold may be based on multiple criteria, including but not limited to a minimum device temperature and/or a value for device temperature calculated or determined based at least in part on a previous temperature measured in connection with a previous operation (e.g., the program operation corresponding to the data to be read in the current operation) which may, again, be taken generally and/or at the particular location.

The current and previous operations being performed by the NAND flash device may include one or both of a read operation and a program operation. Further, the degree of specificity used to define particular locations at which the current and previous operations are performed, and the particular locations at which the corresponding temperatures are measured (if not generally), may vary. For example, various levels of specificity include, but are not limited to, at the level of a block, a sub-block, a WL, a BL, and/or a cell, in each case included in the NAND-based memory media included in the NAND flash device.

The additional (dummy) operations performed may include read and/or program operations, and the additional operations may be performed to change the temperature of the NAND flash device. In various examples, the additional operations may be performed to heat the NAND flash device. In various examples, the heating is performed to raise the temperature of the NAND flash device so that a current temperature for a read operation is raised above a lower threshold. In various examples, the lower threshold may be established based on a previous temperature of the device recorded in connection with a program operation for the data to be read by the read operation.

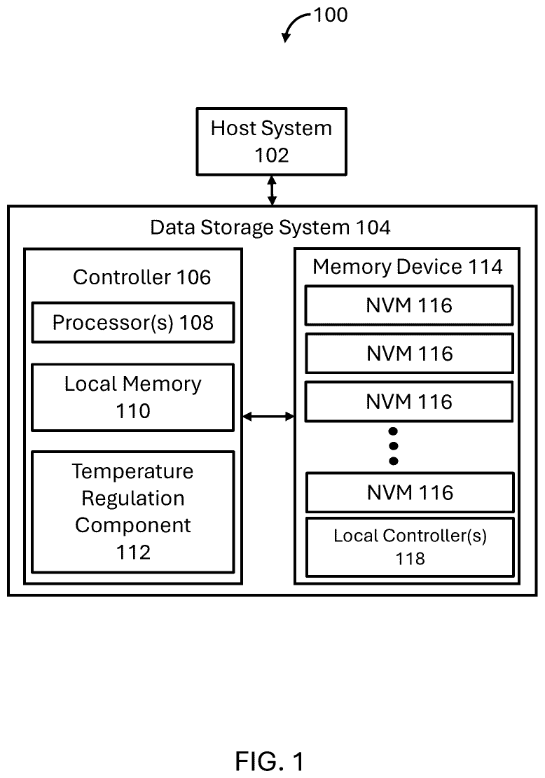

FIG. 1 illustrates an example system 100 including a host system 102 and a data storage system 104. The data storage system 104 may include a controller 106. The controller 106 may include a processor 108, a local memory 110, and temperature regulation component 112. The data storage system 104 may also include a memory device 114. The memory device 114 may be or otherwise include a NAND flash device, such as a solid state drive (SSD). The memory device 114 may include a plurality of NVM media 116 and one or more local controller(s) 118.

In various examples, a read or write request may be received from the host system 102 via a peripheral component interconnect express (PCIe) interface that connects the data storage system 104 to servers or CPUs. PCIe is a standardized interface for motherboard components. The controller 106 may use logical block addresses (LBAs) and physical block addresses (PBAs) to facilitate access for data storage in and retrieval from the NVM media 116. LBAs are an abstraction to allow the operating system to interact with the NVM media 116, and PBAs represent the actual hardware locations within the NVM media 116. To facilitate interacting with the NVM media 116, the controller 106 may create an entry or record that assigns an LBA to a PBA. To keep track of all such LBA-to-PBA assignments, the controller 106 may use a logical-to-physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a data request is received from the host system 102, the controller 106 references the L2P mapping table to determine the PBA within the NVM media 116 corresponding to a desired LBA. Once the PBA is determined, the controller 106 accesses the appropriate NVM media 116 to write or read the data. Access to the NVM media 116 may be via a flash physical (PHY) interface. The controller 106 may employ an error correction code (ECC) operation during encoding and decoding data to detect and correct errors and enhance data integrity. Additionally, the memory device 114 may support a direct memory access (DMA) operation enabling data to be written from the host system 102 directly to the NVM media 116 and read from the NVM media 116 directly to the host system 102. Certain commands may be issued to the controller 106 or the local controller(s) 118 using the host command layer, or non-volatile memory express management interface (NVMe-MI).

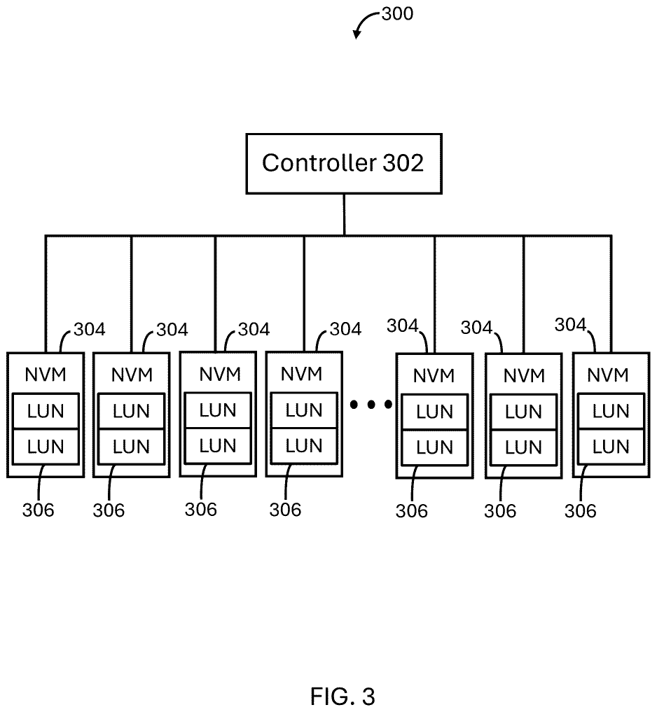

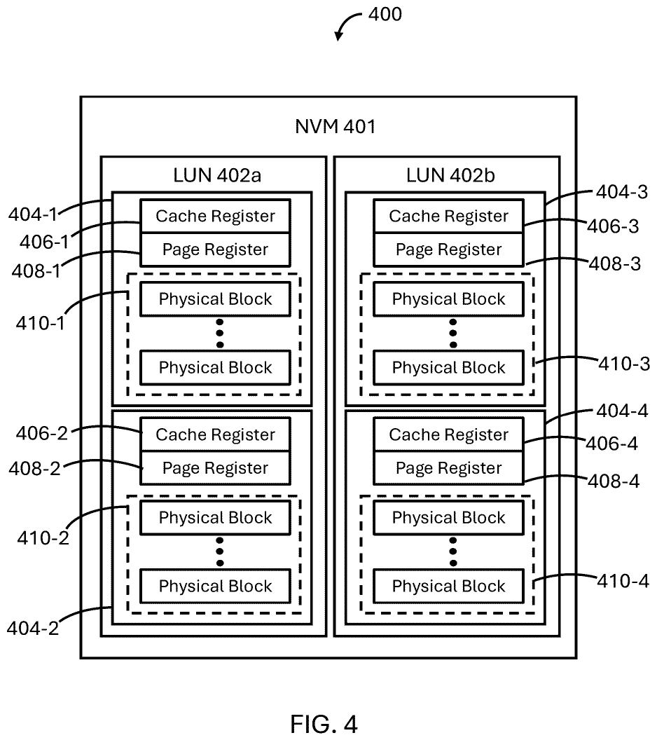

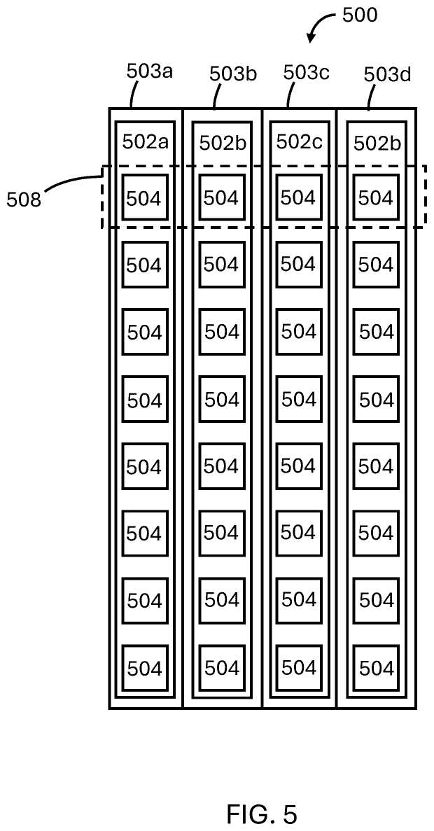

Each of the NVM media 116 may include a plurality of LUNs (e.g., the LUNs 306 of FIG. 3). Each LUN may include a plurality of planes (e.g., the planes 404-1, 4042, 4043, 404-4 of FIG. 4). Each plane may include a plurality of physical blocks (e.g., the physical blocks 410-1, 410-2, 410-3, 410-4 of FIG. 4). Each block may include a set of pages (e.g., the pages 504 of FIG. 5). Each physical block may include a set of WLs corresponding to the pages. Respective ones of the physical blocks may be organized into a multi-plane block (e.g., the multi-plane block 500 of FIG. 5). Each multi-plane block may include one (1) physical block from each plane of one (1) LUN. Each multi-plane block may include a set of multi-plane WLs (e.g., the multi-plane WL 508 of FIG. 5). Each multi-plane WL may include corresponding WLs of the physical blocks included in a multi-plane block such that each multi-plane WL includes one (1) WL from each plane of the multi-plane block. User data may be written to the pages of a multi-plane WL.

The temperature regulation component 112 may reduce errors (e.g., read errors) in the memory device 114 by reducing cross-temperature experienced by the memory device 114. “Cross-temperature” in NAND flash devices, such as SSDs, are instances where data is read at a temperature which is significantly different than the temperature at which the data was programmed/written. Cross-temperature compromises reliability of operations performed on/by the memory device and can even shorten the lifespan of the device itself.

The temperature regulation component 112 may monitor/measure the temperature of read and/or program operations performed by example system 100 (e.g., performed by memory device 114). A temperature sensor (not shown) included in the system 104 (e.g., in the temperature regulation component 112 and/or the memory device 114) may be responsible for measuring/monitoring temperature. In various examples, however, other computational methods for determining a temperature of the data storage system 104 (or more particularly, of the memory device 114 and/or one or more of the NVM 116) may be used to determine the temperature of read and/or program operations without departing from the scope of the present disclosure.

The temperature regulation component 112 may monitor or otherwise determine the temperature, whether continuously, in intervals, and/or based on or in connection with occurrence of read and/or program operations. For example, the temperature regulation component 112 may automatically cause temperature to be sensed or otherwise determined during performance of each read or program operation. In various examples, a determination of temperature may be made within a given time span of each such read and/or program operation by the temperature regulation component 112. The temperature regulation component 112 may perform such monitoring of the memory device 114 to, e.g., reduce temperature mismatch (or cross-temperature) read errors.

In various examples, a present or current temperature-e.g., determined in connection with or in anticipation of a requested current read operation-may be compared to/against criteria for the current read operation. The criteria may include a threshold and/or other variables or criteria for determining whether and to what extent the temperature of memory device 114 needs to be changed (e.g., increased) to successfully perform the read operation.

Additionally and/or alternatively, a difference between a program operation temperature determined in connection with a program operation, and a read operation temperature determined in connection with an attempted, actual, or anticipated read operation, may be calculated. This difference may then be compared to criteria, which may include a threshold and/or other variables or criteria for determining whether and to what extent temperature of the memory device 114 needs to be changed. The criteria or threshold to/against which the determined temperature/temperature difference is compared may be stored locally in local memory 110 of data storage system 104, and/or locally on host system 102.

In various examples, the temperature of the memory device 114 may be changed responsive to determining that a difference between the temperature of the program operation and the current temperature (determined in connection with the read operation) satisfies criteria for changing the temperature of the memory device 114. For example, a lower threshold temperature for the current read operation may be established by subtracting a value from the temperature measured in connection with the previous program operation. The determined temperature difference, when compared to the lower threshold temperature, may indicate that the current temperature is too low relative to the threshold. Responsive to the determination, dummy operation(s) may be performed to increase the temperature of the memory device 114 to or above the threshold temperature. This may increase the likelihood that the read operation will be successfully performed. Accordingly, the criteria may comprise a threshold for the temperature difference, which, if satisfied, triggers, e.g., the performance of additional operations. The additional or dummy operations may be performed on unused portions (e.g., blocks) of the memory device 114 for purposes of changing the temperature of the memory device 114. Performance of the additional operations on/by the memory device 114 may lead to an increase in the temperature of the memory device 114, thereby reducing cross-temperature.

In various examples, the additional operations performed responsive to determining that the temperature of the NAND flash device (e.g., memory device 114) needs to be changed may be performed on unused NAND blocks included therein, blocks of the NAND flash device that are scheduled for garbage collection, or a combination thereof. Further, the additional operations may be “dummy” operations in that they are (i) not requested by a host (e.g., the host system 102) and/or (ii) are of lower priority than the operation(s) currently being performed by the NAND flash device and for which the temperature is to be changed.

In various examples, the temperature regulation component 112 included in the controller 106 may further determine a second (current) temperature of the memory device 114 following the performance of the additional operation(s). The temperature regulation component 112 may then determine whether the second temperature is sufficient for performance of the current operation. Responsive to determining that the second temperature is sufficient for performance of the current operation, the current operation may be performed. Alternatively, responsive to determining that the second temperature is not sufficient for performance of the current operation, second additional operation(s) may be performed on the memory device 114 to heat the device.

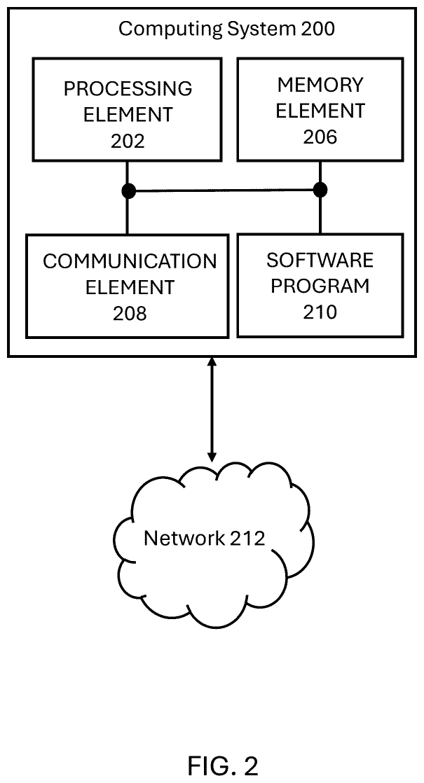

FIG. 2 illustrates a computing system 200 connected to a communication network 212. The computing system 200 may include at least one processing element 202, at least one memory element 206, a communication element 208, and a software program 210. In various examples, the computing system 200 may be a host system (e.g., the host system 102 of FIG. 1) and/or a data storage system (e.g., the data storage system 104 of FIG. 1), without limitation.

The software program 210 may be configured with instructions for performing and/or enabling performance of at least some of the steps set forth herein. In an embodiment, the software program 210 comprises instructions stored on computer-readable media of memory element 206. In various examples, the software program 210 may include instructions for performing operations of the temperature regulation component 112 discussed with reference to FIG. 1.

The communication network 212 generally allows communication between the computing system 200 and another computing device, such as between a remote host system (e.g., the host system 102), a local host system, and/or a data storage system (e.g., the data storage system 104 of FIG. 1), without limitation.

The communication network 212 may include the Internet, cellular communication networks, local area networks, metro area networks, wide area networks, cloud networks, plain old telephone service (POTS) networks, and the like, or combinations thereof. The communication network 212 may be wired, wireless, or combinations thereof and may include components such as modems, gateways, switches, routers, hubs, access points, repeaters, towers, and the like. The computing system 200 may, for example, connect to the communication network 212 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The communication element 208 generally allows communication between the computing system 200 and the communication network 212. The communication element 208 may include signal or data transmitting and receiving circuits, such as antennas, amplifiers, filters, mixers, oscillators, digital signal processors (DSPs), and the like. The communication element 208 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard, such as WiFi, IEEE 802.16 standard, such as WiMAX, Bluetooth™, or combinations thereof. In addition, the communication element 208 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 208 may establish communication through connectors or couplers that receive metal conductor wires or cables, like Cat 6 or coax cable, which are compatible with networking technologies such as ethernet. In certain embodiments, the communication element 208 may also couple with optical fiber cables. The communication element 208 may respectively be in communication with the processing element 202 and/or the memory element 206.

The memory element 206 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof. In some embodiments, the memory element 206 may be embedded in, or packaged in the same package as, the processing element 202. The memory element 206 may include, or may constitute, a “computer-readable medium.” The memory element 206 may store the instructions, code, code segments, software, firmware, programs, applications, apps, services, daemons, or the like that are executed by the processing element 202. In an embodiment, the memory element 206 respectively store the software applications/program 210. The memory element 206 may also store settings, data, documents, sound files, photographs, movies, images, databases, and the like. In various examples, the memory element 206 may include a first memory component (e.g., the local memory 110 of FIG. 1) and one or more SSDs (e.g., the memory device 114 of FIG. 1).

The processing element 202 may include electronic hardware components such as processors. The processing element 202 may include digital processing unit(s). The processing element 202 may include microprocessors (single-core and multi-core), microcontrollers, digital signal processors (DSPs), field-programmable gate arrays (FPGAs), analog and/or digital application-specific integrated circuits (ASICs), or the like, or combinations thereof. The processing element 202 may generally execute, process, or run instructions, code, code segments, software, firmware, programs, applications, apps, processes, services, daemons, or the like. For instance, the processing element 202 may execute the software applications/program 210. The processing element 202 may also include hardware components such as finite-state machines, sequential and combinational logic, and other electronic circuits that can perform the functions necessary for the operation of the current disclosure. The processing element 202 may be in communication with the other electronic components through serial or parallel links that include universal busses, address busses, data busses, control lines, and the like.

FIG. 3 illustrates an example data storage system 300 including a controller 302 and a plurality of NVM media 304. In various examples, the data storage system 300 may correspond to the data storage system 104 of FIG. 1, the controller 302 may correspond to the controller 106 of FIG. 1, and the NVM media 304 may correspond to the NVM media 116 of FIG. 1, without limitation. In various examples, the NVM media 304 may each include two LUNs 306. It would be appreciated by one of ordinary skill in the art that each NVM 304 may include more than two LUNs, without limitation. Each LUN 306 may correspond to a respective die of the NVM media 304. In various examples, the controller 302 may write incoming data to more than one NVM media 304 in parallel. The NVM media 304 may write incoming data to more than one LUN 306 in parallel. Each LUN 306 may include a set of multi-plane blocks.

FIG. 4 illustrates an example NVM media 400. The NVM 400 may correspond to the NVM media 116 of FIG. 1 and/or the NVM media 304 of FIG. 3, without limitation. The NVM media 400 may include a LUN 402a and a LUN 402b. The LUN 402a may include a plane 404-1 and a plane 404-2. The plane 404-1 may include a cache register 406-1, a page register 408-1, and physical blocks 410-1. The plane 404-2 may include a cache register 406-2, a page register 408-2, and physical blocks 410-2. The LUN 402b may include a plane 404-3 and a plane 404-4. The plane 404-3 may include a cache register 406-3, a page register 408-3, and physical blocks 410-3. The plane 404-4 may include a cache register 406-4, a page register 408-4, and physical blocks 410-4. It would be appreciated by one of ordinary skill in the art that the NVM media 400 may include more than two (2) die and each die may include more than two (2) planes. In various examples, the NVM media 400 may include two (2), four (4), eight (8), sixteen (16), twenty four (24), thirty two (32), or more die, without limitation. Each die may include, for example, four (4), six (6), eight (8), or more planes, without limitation.

When data is written to or retrieved from the LUN 402a or the LUN 402b, the data may be temporarily stored in one of the cache registers 406-1, 406-2, 406-3, 406-4 and/or the page registers 408-1, 408-2, 408-3, 408-4. The cache registers 406-1, 406-2, 406-3, 406-4 and the page registers 408-1, 408-2, 408-3, 408-4 may respectively have an equivalent data capacity of one page. Accordingly, data to be written to one page of one of the physical blocks 410-1 may be temporarily stored in the cache register 406-1 while data to be written to another page of one of the physical blocks 410-1 may be temporarily stored in the page register 408-1. Data being read from a page of one of the physical blocks 410-1 may be retrieved and temporarily stored in the page register 408-1 while data read from a page of another one of the physical blocks 410-1 may transferred from the cache register 406-1 to a controller (e.g., the controller 104 of FIG. 1). Accordingly, the cache register and page register enable double buffering of data to reduce data programming and read times. Each page may include a plurality of cells. Data bits may be written to the plurality of cells on a WL-by-WL basis. Data may be erased from the plurality of cells on a physical block basis.

In various examples, a first set of multi-plane blocks may be formed across the planes 404-1, 404-2 of the LUN 402a and a second set of multi-plane blocks may be formed across the planes 404-3, 404-4 of the LUN 402b. Each multi-plane block of the first set of multi-plane blocks may include one (1) physical block from the plane 404-1 and one (1) physical block from the plane 404-2. Each multi-plane block of the second set of multi-plane blocks may include one (1) physical block from the plane 404-3 and one (1) physical block from the plane 404-4. For example, a first multi-plane block may include a first one of the physical blocks 410-1 and a first one of the physical blocks 410-2. A second multi-plane block may include a first one of the physical blocks 410-3 and a first one of the physical blocks 410-4.

Each multi-plane block may include a multi-plane WL (e.g., the multi-plane WL 508 of FIG. 5). Accordingly, each set of multi-plane blocks may include a corresponding set of multi-plane WLs. For example, a first multi-plane WL may include a WL of one of the physical blocks 410-1 and a WL of one of the physical blocks 410-2. A second multi-plane WL may include a WL from one of the physical blocks 410-3 and a WL of one of the physical blocks 410-4. In an example, a multi-plane WL may include one (1) WL from each plane 404-1, 404-2, 404-3, 404-4. A multi-plane block may include one (1) physical block 410-1 from the plane 404-1, one (1) physical block 410-2 from the plane 404-2, one (1) physical block 410-3 from the plane 404-3, and one (1) physical block 410-4 from the plane 404-4. The WLs or physical blocks that make up a multi-plane WL or multi-page block may or may not be in a same location of each plane of a corresponding one of the LUNs 402a, 402b.

FIG. 5 illustrates a multi-plane block 500 of an NVM (e.g., the NVM 116 of FIG. 1). The multi-plane block may include physical blocks 502a, 502b, 502c, 502d. The physical blocks 502a, 502b, 502c, 502d may be included in a set of planes 503a, 503b, 503c, 503d. Each physical block 502a, 502b, 502c, 502d may include a set of pages 504. A multi-plane WL 508 may be formed to include a page 504 of each physical block 502a, 502b, 502c, 502d.

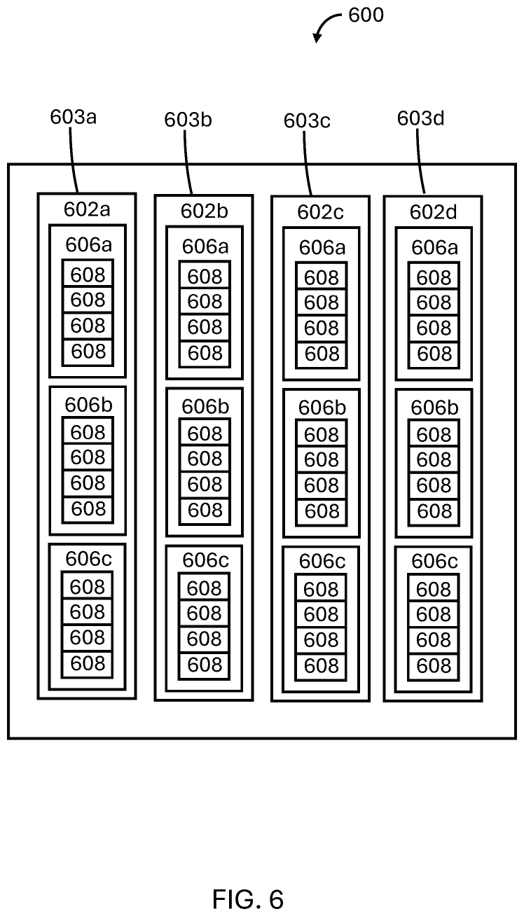

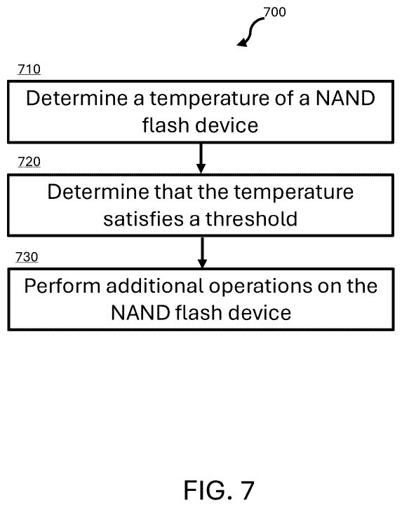

FIG. 6 illustrates a multi-plane WL 600 of a multi-plane block (e.g., the multi-plane block 500 of FIG. 5). The multi-plane WL 600 may include pages 602a, 602b, 602c, 602d. The pages 602a, 602b, 602c, 602d may be included in a set of physical blocks 603a, 603b, 603c, 603d that make up the multi-plane block. The pages 602a, 602b, 602c, 602d may be TLC pages that include TLC cells. Accordingly, each of the pages 602a, 602b, 602c, 602d may include an upper page 606a, a middle page 606b, and a lower page 606c. It would be appreciated by one of ordinary skill in the art that the pages 602a, 602b, 602c, 602d could include SLC pages, MLC pages, TLC, QLC pages, and/or PLC pages without departing from the spirit of the present disclosure. A plurality of data frames 608 may be stored in each of the upper pages 606a, middle pages 606b, and lower pages 606c.

Through hardware, software, firmware, or various combinations thereof, any of the processing elements (e.g., the controller 106 and/or local controller(s) of FIG. 1, the processing element 202 of FIG. 2, and/or the controller 302 of FIG. 3) may-alone or in combination with other processing elements-be configured to perform the operations of embodiments of the present disclosure. The embodiments described herein in connection with the attached drawing figures are intended to describe aspects of the disclosure in sufficient detail to enable those skilled in the art to practice the disclosure. Other embodiments can be utilized and changes can be made without departing from the scope of the present disclosure. The system may include additional, less, or alternate functionality and/or device(s), including those discussed elsewhere herein. The above and below detailed description is, therefore, not to be taken in a limiting sense. The scope of the present disclosure is defined only by the appended claims, along with the full scope of equivalents to which such claims are entitled, unless otherwise expressly stated and/or readily apparent to those skilled in the art from the description.

FIG. 7 illustrates a method 700 for increasing reliability of a current operation being or anticipated to be performed by a NAND flash device, such as the memory device 114 of FIG. 1.

At operation 710, a temperature of a NAND flash device is determined. In accordance with examples of the present disclosure, the temperature regulation component 112 of controller 106 may be used to determine the temperature, e.g., via a temperature sensor included therein and/or in the memory device 114. In various examples, the current temperature may be determined responsive to a read request from the host (e.g., Host System 102). The current temperature may be measured generally for the memory device 114, and/or in a more targeted location at or near the particular NVM 116 where the anticipated read is to be performed. In one or more embodiments, temperature measurement location is consistent with the location at which temperature was measured in connection with a previous program operation for the data that is to be read.

At operation 720, a controller determines that the temperature determined at operation 710 satisfies criteria, such as a threshold. The determination may be made at the controller 106, for example. The threshold may be either a value for minimum device temperature or a value for device temperature calculated based at least in part on a previously-measured temperature. For example, the previously-measured temperature may have been determined in connection with a previous operation performed at/on a particular location within the memory device 114 (i.e., the program operation writing the data that is to be read in the current read operation). In various examples, the flash controller 106 may define the particular location using designations with one or more of the following levels of specificity: a block, a sub-block, a WL, a BL, and a cell. As noted above, in some examples, the previous operation may be a program operation while the current operation may be a read operation.

At operation 730, responsive to determining that the threshold is satisfied, additional operations may be performed on the NAND flash device. The operations may be performed at or on one or more of the NVM 116, without limitation. Examples of additional operations which may be performed on the NAND flash device include one or both of read operations(s) and program operation(s). In accordance with the present disclosure, the additional operations may be performed to heat the NAND flash device.

In various examples, the additional operations may be performed on unused NAND blocks of the NAND flash device and/or blocks of the NAND flash device that are scheduled for garbage collection.

In various examples, the additional operations are either not requested by the host, or are of lower priority than the current operation, and may be considered dummy operations. In various examples, the current operation (e.g., the read operation which was requested and triggered method 700), is performed following and/or based on performance of the additional operations.

The method 700 may also or alternatively include determining, e.g., by the (flash) controller 106, a second (current) temperature of the NAND flash device following the performance of the additional operations at operation 730. The second temperature may be measured by the same component(s) as the current or first temperature discussed in more detail above, e.g., by the temperature regulation component 112 included in the controller 106, and may be sensed/measured at the same location at which the first temperature was taken or at a different location within the NAND flash device (e.g., memory device 114). The method 700 may further include determining that the second temperature is sufficient for performance of the current operation, and, responsive to determining the sufficiency for the current operation, the method 700 may include performing the current operation.

Alternatively, the method 700 may include determining that the second temperature is not sufficient for performance of the current operations. In these cases, responsive to determining the insufficiency for the current operation, the method 700 may further include performing second additional operations on the NAND flash device to heat the NAND flash device.

### Feature Combinations

According to various examples of the present disclosure, computer-implemented methods for increasing reliability of a current operation being performed by a NAND flash device (such as an SSD) may include performing the following operations via a flash controller: determining a temperature of the NAND flash device; determining that the temperature satisfies a threshold; and, responsive to the determination that the threshold is satisfied, performing additional operations on the NAND flash device.

In combination with any of the previous examples, the additional operations performed on the NAND flash device may include one or both of read operation(s) and program operations(s). Further, the additional operations performed on the NAND flash device may heat the NAND flash device.

In combination with any of the previous examples, the current operation being performed by the NAND flash device is to be performed at a particular location within NAND-based memory media of the NAND flash device (e.g., the NVM 116 of FIG. 1). The flash controller may define the particular location using one or more of the following designations: a block, a sub-block, a word line, a bit line, and a cell.

In combination with any of the previous examples, the threshold against which the temperature of the NAND flash device is compared may be either (i) a value for minimum device temperature, or (ii) a value for device temperature calculated based at least in part on a previous temperature measured in connection with a previous operation performed on/in the particular location. Additionally, the threshold may be the value for device temperature calculated based at least in part on the previous temperature measured in connection with the previous operation on the particular location, the previous operation being a program operation and the current operation being a read operation.

In combination with any of the previous examples, the additional operations are performed on one or both of: unused NAND blocks of the NAND flash device, and blocks of the NAND flash device that are scheduled for garbage collection. Further, the additional operations may be either (i) not requested by a host, or (ii) of lower priority than the current operation.

In combination with any of the previous examples, the flash controller may further perform operations for: determining a second temperature of the NAND flash device following the performance of the additional operations; determining that the second temperature is sufficient for performance of the current operation; and, responsive to determining the sufficiency for the current operation, performing the current operation.

In combination with any of the previous examples, the flash controller may further perform operations for: determining a second temperature of the NAND flash device following the performance of the additional operations; determining that the second temperature is not sufficient for performance of the current operation; and, responsive to determining the insufficiency for the current operation, performing second additional operations on the NAND flash device to heat the NAND flash device. These cycles of additional operations and temperature measurement (and comparison against a threshold temperature) may be repeated until the threshold is satisfied and the current read operation is consequently performed.

### General Considerations

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A computer-implemented method for increasing reliability of a current operation performed by a NAND flash device, the method comprising performing the following via a flash controller:
determining a temperature of the NAND flash device;
determining that the temperature satisfies a threshold; and
responsive to the determination that the threshold is satisfied, performing additional operations on the NAND flash device.

2. The computer-implemented method of claim 1, wherein the additional operations include one or both of read operation(s) and program operation(s).

3. The computer-implemented method of claim 1, wherein the additional operations heat the NAND flash device.

4. The computer-implemented method of claim 1, wherein the current operation is to be performed at a particular location within NAND-based memory media of the NAND flash device, and wherein the threshold is either: (i) a value for minimum device temperature, or (ii) a value for device temperature calculated based at least in part on a previous temperature measured in connection with a previous operation on the particular location.

5. The computer-implemented method of claim 4, wherein the flash controller defines the particular location using one or more of the following designations: a block, a sub-block, a word line, a bit line, and a cell.

6. The computer-implemented method of claim 4, wherein the threshold is the value for device temperature calculated based at least in part on the previous temperature measured in connection with the previous operation on the particular location, the previous operation being a program operation and the current operation being a read operation.

7. The computer-implemented method of claim 1, wherein the additional operations are performed on one or both of: unused NAND blocks of the NAND flash device; and blocks of the NAND flash device that are scheduled for garbage collection.

8. The computer-implemented method of claim 1, wherein the additional operations are either: (i) not requested by a host; or (ii) of lower priority than the current operation.

9. The computer-implemented method of claim 1, further comprising performing the following via the flash controller:
determining a second temperature of the NAND flash device following the performing of the additional operations;
determining that the second temperature is sufficient for performance of the current operation; and
responsive to determining the sufficiency for the current operation, performing the current operation.

10. The computer-implemented method of claim 1, further comprising performing the following via the flash controller:
determining a second temperature of the NAND flash device following the performing of the additional operations;
determining that the second temperature is not sufficient for performance of the current operation; and
responsive to determining the insufficiency for the current operation, performing second additional operations on the NAND flash device to heat the NAND flash device.

11. A NAND flash device controller comprising non-transitory computer-readable media having instructions embodied thereon which, when executed by one or more processors, cause the one or more processors to:
determine a temperature of a NAND flash device;
determine that the temperature satisfies a threshold; and
responsive to the determination that the threshold is satisfied, performing additional operations on the NAND flash device.

12. The non-transitory computer-readable media of claim 11, wherein the additional operations include one or both of read operation(s) and program operation(s).

13. The non-transitory computer-readable media of claim 11, wherein the additional operations heat the NAND flash device.

14. The non-transitory computer-readable media of claim 11, wherein the current operation is to be performed at a particular location within NAND-based memory media of the NAND flash device, and wherein the threshold is either: (i) a value for minimum device temperature, or (ii) a value for device temperature calculated based at least in part on a previous temperature measured in connection with a previous operation on the particular location.

15. The non-transitory computer-readable media of claim 14, wherein the instructions, when executed by the one or more processors, cause the one or more processors to define the particular location using one or more of the following designations: a block, a sub-block, a word line, a bit line, and a cell.

16. The non-transitory computer-readable media of claim 14, wherein the threshold is the value for device temperature calculated based at least in part on the previous temperature measure in connection with the previous operation on the previous location, the previous operation being a program operation and the current operation being a read operation.

17. The non-transitory computer-readable media of claim 11, wherein the additional operations are performed on one or both of: unused NAND blocks of the NAND flash device; and
blocks of the NAND flash device that are scheduled for garbage collection.

18. The non-transitory computer-readable media of claim 11, wherein the additional operations are either: (i) not requested by a host; or (ii) of lower priority than the current operation.

19. The non-transitory computer-readable media of claim 11, wherein the instructions, when executed by the one or more processors, cause the one or more processors to:
determine a second temperature of the NAND flash device following the performing of the additional operations;
determine that the second temperature is sufficient for performance of the current operation; and
responsive to determining the sufficiency for the current operation, performing the current operation.

20. The non-transitory computer-readable media of claim 11, wherein the instructions, when executed by the one or more processors, cause the one or more processors to:
determine a second temperature of the NAND flash device following the performing of the additional operations;
determine that the second temperature is not sufficient for performance of the current operation; and
responsive to determining the insufficiency for the current operation, performing second additional operations on the NAND flash device to heat the NAND flash device.
